(19) United States
(12) Patent Application Publication
(10) Pub. No.: US 2025/0385110 A1
(43) Pub. Date: Dec. 18, 2025

(54) TRANSFER APPARATUS, FRAME UNIT TRANSFER METHOD, AND CHIP MANUFACTURING METHOD

(71) Applicant: DISCO CORPORATION, Tokyo (JP)

(72) Inventor: Takeomi FUKUOKA, Tokyo (JP)

(21) Appl. No.: 19/212,965

(22) Filed: May 20, 2025

(30) Foreign Application Priority Data
Jun. 17, 2024 (JP) 2024-097160
Mar. 4, 2025 (JP) 2025-033387

(51) Int. Cl. H01L 21/67; H01L 21/677; H01L 21/683; H01L 21/78

(52) U.S. Cl. CPC H01L 21/6715; H01L 21/677; H01L 21/6838; H01L 21/78

(57) ABSTRACT

A transfer apparatus includes a pad for holding a frame unit on a holding surface side thereof, a liquid supply unit configured to supply liquid to the holding surface side of the pad, and a moving mechanism configured to move the pad. The holding surface has a first area and a second area surrounding the first area and protruding with respect to the first area. In a state in which the first area faces a plate-shaped object and the second area surrounds the plate-shaped object, the frame unit is held on the holding surface side by use of interfacial tension of liquid in a still state, the liquid being supplied from the liquid supply unit and filling gaps between the first area and the plate-shaped object, and between the second area and the plate-shaped object, and then the moving mechanism moves the pad to transfer the frame unit.

### BACKGROUND OF THE INVENTION

### Field of the Invention

The present invention relates to a transfer apparatus for transferring a frame unit including a plate-shaped object, a frame surrounding the plate-shaped object, and a sheet fixed to both the plate-shaped object and the frame, a frame unit transfer method for transferring the frame unit, and a chip manufacturing method for manufacturing a plurality of chips from a wafer, on which a plurality of devices are formed, included as the plate-shaped object in the frame unit.

### Description of the Related Art

Chips having devices such as integrated circuits (ICs) are indispensable constituent elements in various kinds of electronic equipment such as mobile phones and personal computers. Such chips are manufactured by, for example, forming a plurality of devices on a front surface side of a wafer, grinding a back surface side of the wafer for thinning, and then dividing the wafer along boundaries of the plurality of devices.

Grinding of the back surface side of the wafer is often performed after a sheet is fixed to the front surface of the wafer. In this case, since the back surface side of the wafer can be ground while the plurality of devices formed on the front surface side of the wafer are prevented from being damaged, a reduction in the yield in manufacturing chips from wafers can be prevented.

Transfer of a wafer to which a sheet is fixed is performed by use of, for example, a pad having grooves formed in a holding surface thereof. Water flowing through the grooves generates negative pressure in a space in the vicinity of the holding surface according to the Bernoulli's theorem (refer to Japanese Patent Laid-open No. 2018-129451, for example). Specifically, at the time of the transfer, water is first made to flow from the grooves formed in the holding surface of the pad, thereby causing the space in the vicinity of the holding surface to become negatively pressurized. Owing to the generated negative pressure, the wafer is held on this holding surface side.

Then, while the supply of water flowing through the grooves is stopped, the water fills a gap between the pad and the wafer and is in a still state, providing interfacial tension. According to this interfacial tension, the pad is moved with the wafer held thereon. In this case, drying of the wafer is prevented, so that contamination such as processing swarf that has come into contact with the wafer can be prevented from adhering to the wafer.

Division of a wafer is often performed after the wafer and a frame are integrated through a sheet to form a frame unit. In this case, a plurality of chips manufactured by division of the wafer are prevented from scattering, and the plurality of chips can be transferred together with the frame without being transferred separately.

Transfer of a frame unit including a plate-shaped object such as a wafer or chips is performed by, for example, moving a pad in a state in which liquid is supplied to the plate-shaped object and suction force is caused to act from the pad to a frame (refer to Japanese Patent Laid-open No. 2018-117014, for example). In this case, contamination can be prevented from adhering to the plate-shaped object as described above.

### SUMMARY OF THE INVENTION

In order to hold a wafer by use of a pad capable of causing a space in the vicinity of a holding surface thereof to become negatively pressurized according to the Bernoulli's theorem, it is necessary to form grooves of a special structure in the holding surface of the pad. However, pads having such grooves formed therein tend to require high manufacturing cost.

In order to hold a frame unit on a holding surface side of a pad by causing suction force to act from the pad to a frame, a suction mechanism (ejector or vacuum pump, for example) for generating the suction force is required. However, to make this suction mechanism operate, for example, compressed air for driving the ejector and electric power for driving the vacuum pump are needed to be supplied constantly, leading to increased operating cost in transferring the frame unit.

In view of such circumstances, it is an object of the present invention to provide a transfer apparatus, a frame unit transfer method, and a chip manufacturing method that can suppress adhering of contamination to a plate-shaped object in transferring a frame unit and that can reduce manufacturing cost and operating cost therefor.

In accordance with an aspect of the present invention, there is provided a transfer apparatus for transferring a frame unit including a plate-shaped object, a frame surrounding the plate-shaped object, and a sheet fixed to both the plate-shaped object and the frame. The transfer apparatus includes a pad for holding the frame unit on a holding surface side thereof, a liquid supply unit configured to supply liquid to the holding surface side of the pad, and a moving mechanism configured to move the pad. The holding surface has a first area and a second area surrounding the first area and protruding with respect to the first area. In a state in which the first area faces the plate-shaped object and the second area surrounds the plate-shaped object, the frame unit is held on the holding surface side by use of interfacial tension of the liquid in a still state, the liquid being supplied from the liquid supply unit and filling gaps between the first area and the plate-shaped object, and between the second area and the plate-shaped object, and then the moving mechanism moves the pad to transfer the frame unit.

In the transfer apparatus according to the present invention, preferably, the frame unit is transferred in a state in which the second area faces a portion of the sheet positioned between the plate-shaped object and the frame. Further, in the transfer apparatus according to the present invention, preferably, the holding surface further has a third area surrounding the second area and being recessed with respect to the second area, and the frame unit is transferred in a state in which the third area faces the frame. Further, in the transfer apparatus according to the present invention, preferably, the liquid supply unit supplies the liquid through a communication passage that is open in the first area.

In accordance with another aspect of the present invention, there is provided a frame unit transfer method for transferring a frame unit including a plate-shaped object, a frame surrounding the plate-shaped object, and a sheet fixed to both the plate-shaped object and the frame. The frame unit transfer method includes adjusting the frame unit and a pad in position relative to each other such that a first area of a holding surface of the pad faces the plate-shaped object and that a second area surrounding the first area and protruding with respect to the first area surrounds the plate-shaped object, after the frame unit and the pad are adjusted in position relative to each other, holding the frame unit on the holding surface side by use of interfacial tension of the liquid in a still state, the liquid filling gaps between the first area and the plate-shaped object, and between the second area and the plate-shaped object, and transferring the frame unit by moving the pad while the frame unit is kept being held on the holding surface side by use of the interfacial tension of the liquid in the still state, the liquid filling the gaps.

In accordance with a further aspect of the present invention, there is provided a chip manufacturing method for manufacturing a plurality of chips from a wafer of a first frame unit including the wafer having a plurality of devices formed thereon, a frame surrounding the wafer, and a sheet fixed to both the wafer and the frame. The chip manufacturing method includes obtaining a second frame unit including a plurality of chips manufactured by division of the wafer along boundaries of the plurality of devices on a processing table, adjusting the second frame unit and a pad in position relative to each other such that a first area of a holding surface of the pad faces the plurality of chips and that a second area surrounding the first area and protruding with respect to the first area surrounds the plurality of chips, after the second frame unit and the pad are adjusted in position relative to each other, holding the second frame unit on the holding surface side by use of interfacial tension of the liquid in a still state, the liquid filling gaps between the first area and the plurality of chips, and between the second area and the plurality of chips, and transferring the second frame unit to be separated from the processing table by moving the pad while the second frame unit is kept being held on the holding surface side by use of the interfacial tension of the liquid in the still state, the liquid filling the gaps.

In the present invention, the gaps between the first area of the holding surface of the pad and the plate-shaped object, and between the second area of the holding surface of the pad and the plate-shaped object are filled with the liquid in the still state. In this case, drying of the plate-shaped object is prevented. Therefore, in the present invention, contamination can be prevented from adhering to the plate-shaped object.

Further, in the present invention, the frame unit is held on the holding surface side by use of interfacial tension of the liquid in the still state. In this case, it is not necessary to form grooves for causing a space in the vicinity of the holding surface to become negatively pressurized according to the Bernoulli's theorem, in the holding surface of the pad. Thus, manufacturing cost of the pad can be reduced compared to a case in which such grooves are formed in the holding surface of the pad.

Moreover, in the present invention, the frame unit is transferred by moving the pad while the frame unit is kept being held on the holding surface side by use of the interfacial tension of the liquid in the still state. In this case, no suction mechanism is required to transfer the frame unit. Thus, in the present invention, operating cost can be reduced compared to a case in which such a suction mechanism is used to transfer the frame unit.

The above and other objects, features and advantages of the present invention and the manner of realizing them will become more apparent, and the invention itself will best be understood from a study of the following description and appended claims with reference to the attached drawings showing some preferred embodiments of the invention.

### BRIEF DESCRIPTION OF THE DRAWINGS

FIG. 1 is a perspective view schematically illustrating an example of a frame unit;

FIG. 2 is a perspective view schematically illustrating an example of a transfer apparatus;

FIG. 3A is a cross-sectional view illustrating a cross section of a pad and the like, taken along a line IIIA-IIIA indicated in FIG. 2;

FIG. 3B is a perspective view illustrating a lower surface (holding surface) side of the pad;

FIG. 4 is a flowchart schematically illustrating an example of a frame unit transfer method;

FIG. 5A is a cross-sectional view schematically illustrating how a position adjusting step is performed;

FIG. 5B is a cross-sectional view schematically illustrating how the position adjusting step is performed;

FIG. 6A is a cross-sectional view schematically illustrating how a holding step is performed;

FIG. 6B is a cross-sectional view schematically illustrating how a transfer step is performed;

FIG. 7A is a cross-sectional view schematically illustrating how the transfer step is performed;

FIG. 7B is a cross-sectional view schematically illustrating how the transfer step is performed;

FIG. 8 is a flowchart schematically illustrating an example of a chip manufacturing method for manufacturing a plurality of chips from a wafer of the frame unit;

FIG. 9 is a perspective view schematically illustrating an example of a transfer apparatus used in the chip manufacturing method illustrated in FIG. 8;

FIG. 10 is a perspective view schematically illustrating an example of a processing apparatus used in the chip manufacturing method illustrated in FIG. 8;

FIG. 11 is a perspective view schematically illustrating how a chip manufacturing step is performed; and

FIG. 12 is a flowchart schematically illustrating another example of the chip manufacturing method for manufacturing the plurality of chips from the wafer of the frame unit.

### DETAILED DESCRIPTION OF THE PREFERRED EMBODIMENTS

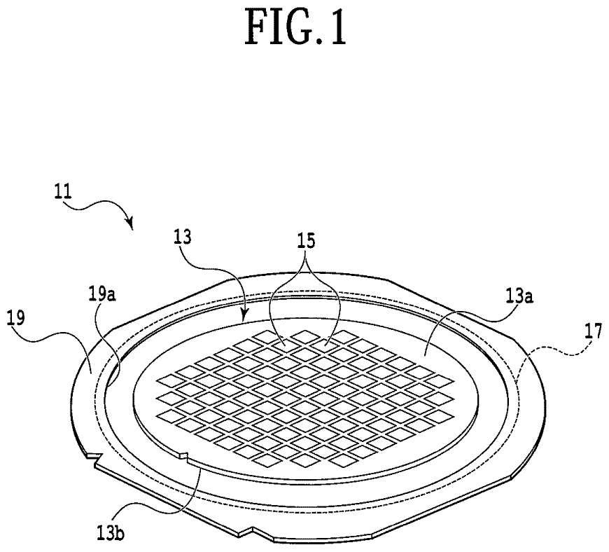

Embodiments of the present invention are described with reference to the accompanying figures. FIG. 1 is a perspective view schematically illustrating an example of a frame unit. A frame unit 11 illustrated in FIG. 1 has a wafer 13 that is, for example, made of a single crystal material such as silicon (Si), silicon carbide (Sic), or gallium nitride (GaN) and that has its front surface 13a exposed.

Further, a plurality of devices 15 arranged in a matrix form are formed on the front surface 13a side of the wafer 13. In other words, boundaries of the plurality of devices 15 extend in a lattice shape on the wafer 13. It is to be noted that each of a plurality of straight-line portions included in the boundaries is referred to also as a planned division line. In addition, the wafer 13 has a back surface 13b fixed to a central area of a disk-shaped sheet 17 having a diameter larger than a diameter of the wafer 13.

The sheet 17 has, for example, a base material in a flexible film shape and an adhesive layer (paste layer) provided on the wafer 13 side of the base material. Alternatively, the sheet 17 may have the base material only. That is, the sheet 17 does not need to have an adhesive layer. In the case in which the sheet 17 has no adhesive layer, for example, the wafer 13 and the sheet 17 are fixed to each other by thermocompression bonding.

It is to be noted that the base material is made of a material such as polyolefin (PO), polyethylene terephthalate (PET), polyvinyl chloride (PVC), or polystyrene (PS). The adhesive layer is made of an ultraviolet-curable material such as a silicone rubber, an acrylic material, an epoxy material, or the like.

Moreover, an annular frame 19 having a circular opening 19a larger in diameter than the wafer 13 is fixed to an outer peripheral area of the sheet 17. The frame 19 is, for example, made of an alloy material such as stainless steel or an aluminum alloy. It is to be noted that, in the case in which the sheet 17 has no adhesive layer, the frame 19 and the sheet 17 are fixed to each other by thermocompression bonding as in the case of fixing the wafer 13 and the sheet 17 to each other.

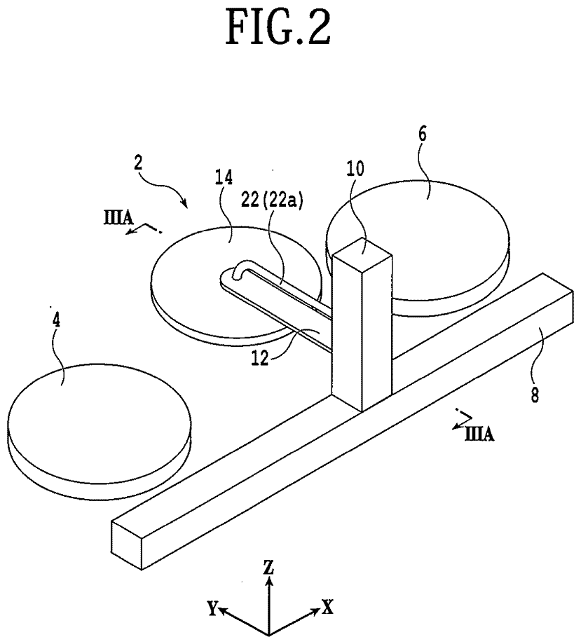

FIG. 2 is a perspective view schematically illustrating an example of a transfer apparatus that is used to transfer the frame unit 11. It is to be noted that a direction (X direction) indicated by an arrow X and a direction (Y direction) indicated by an arrow Y in FIG. 2 are directions orthogonal to each other in a horizontal plane and that a direction (Z direction) indicated by an arrow Z is a direction (vertical direction) orthogonal to each of the X direction and the Y direction.

A transfer apparatus 2 illustrated in FIG. 2 is used, for example, when the frame unit 11 placed on a transfer source table 4 is transferred to a transfer destination table 6 separated from the transfer source table 4 in the X direction. The transfer apparatus 2 has an X-direction moving mechanism 8. It is to be noted that FIG. 2 illustrates the X-direction moving mechanism 8 by a rectangular parallelepiped extending along the X direction for convenience.

The X-direction moving mechanism 8 includes, for example, an X-direction ball screw extending along the X direction, a motor coupled to one end portion of a screw shaft of the X-direction ball screw, a pair of X-direction guide rails each extending along the X direction and sandwiching the screw shaft in the Y direction, and an X-direction movable plate that is slidably coupled to upper surface sides of the pair of X-direction guide rails and fixed to an upper surface side of a nut of the X-direction ball screw.

When the motor of the X-direction moving mechanism 8 is actuated, the screw shaft of the X-direction ball screw rotates, and the X-direction movable plate moves along the pair of X-direction guide rails together with the nut. Further, a Z-direction moving mechanism 10 is provided to an upper surface of the X-direction movable plate. It is to be noted that, in FIG. 2, the Z-direction moving mechanism 10 is illustrated as a rectangular parallelepiped extending along the Z direction for convenience.

The Z-direction moving mechanism 10 includes, for example, a Z-direction ball screw disposed along the Z direction, a motor coupled to one end portion of a screw shaft of the Z-direction ball screw, a pair of Z-direction guide rails each extending along the Z direction and sandwiching the screw shaft in the X direction, and a Z-direction movable plate that is slidably coupled to side surface sides of the pair of Z-direction guide rails and fixed to a side surface side of a nut of the Z-direction ball screw.

When the motor of the Z-direction moving mechanism 10 is actuated, the screw shaft of the Z-direction ball screw rotates, and the Z-direction movable plate moves along the pair of Z-direction guide rails together with the nut. In addition, a base end portion of an arm 12 extending along the Y direction is fixed to a side surface of the Z-direction movable plate.

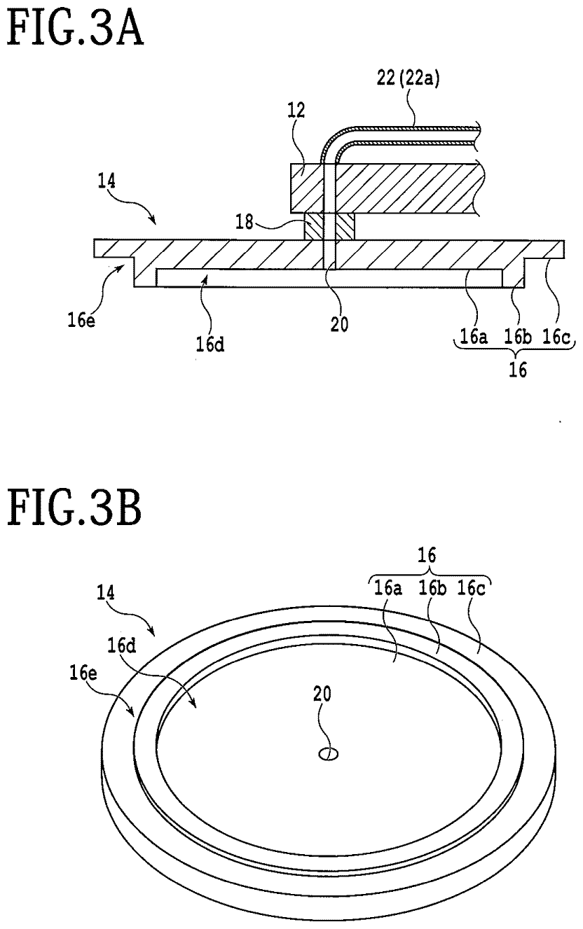

To a lower side of a distal end portion of the arm 12, provided is a pad 14 for holding the frame unit 11 on a lower surface (holding surface) side thereof. FIG. 3A is a cross-sectional view illustrating a cross section of the pad 14 and the like, taken along a line IIIA-IIIA indicated in FIG. 2, and FIG. 3B is a perspective view illustrating a lower side of the pad 14.

A holding surface 16 of the pad 14 includes a circular first area 16a, an annular second area 16b surrounding the first area 16a and protruding with respect to the first area 16a, and a third area 16c surrounding the second area 16b and being recessed with respect to the second area 16b. In other words, the holding surface 16 has, when seen from obliquely below, a recess 16d including the first area 16a as a bottom surface, and a step 16e including the second area 16b as an upper stage surface and the third area 16c as a lower stage surface.

It is to be noted that both a diameter of the first area 16a and an outer diameter of the second area 16b are larger than the diameter of the wafer 13 and smaller than the diameter of the opening 19a of the frame 19. Further, a distance between the first area 16a and the second area 16b in the Z direction (depth of the recess 16d) is, for example, substantially equal to a thickness of the wafer 13. A distance between the second area 16b and the third area 16c in the Z direction (level difference of the step 16e) is, for example, substantially equal to a thickness of the frame 19.

The pad 14 is, for example, made of a plastic such as a super engineering plastic like polyether ether ketone (PEEK) and the like or a carbon fiber reinforced plastic (CFRP). Alternatively, the pad 14 may be made of a material having high hydrophilicity such as titanium oxide, glass, or aluminum. Further alternatively, in the pad 14, a portion in the vicinity of the holding surface 16 may be made of a material having high hydrophilicity while other portions may be made of another material (plastic, for example).

On an upper side of the pad 14, there is provided a coupling member 18 having a lower end portion fixed to a center of the pad 14 and an upper end portion fixed to the lower side of the distal end portion of the arm 12. In addition, a communication passage 20 extending along the Z direction is formed through the distal end portion of the arm 12, the coupling member 18, and the pad 14. A position in the Y direction (Y coordinates) of a center of the communication passage 20 coincides, for example, with Y coordinates of respective centers of the transfer source table 4 and the transfer destination table 6.

The communication passage 20 communicates with a liquid supply unit 22. The liquid supply unit 22 includes a pipe 22a having one end portion fixed to an upper side of the distal end portion of the arm 12, and a liquid supply source (not illustrated) that can communicate with the communication passage 20 through the pipe 22a. When the liquid supply source is actuated, liquid (water, for example) is supplied to the holding surface 16 side of the pad 14 through the pipe 22a and the communication passage 20.

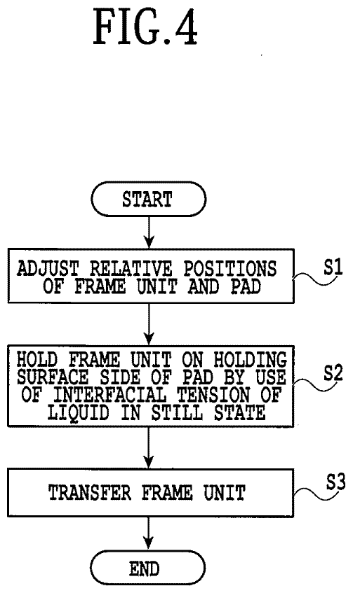

FIG. 4 is a flowchart schematically illustrating an example of a frame unit transfer method for transferring the frame unit 11 by use of the transfer apparatus 2. In this method, the frame unit 11 placed on the transfer source table 4 such that the front surface 13a of the wafer 13 is oriented upward and the wafer 13 has its center overlapping the center of the transfer source table 4 in the Z direction is transferred to the transfer destination table 6.

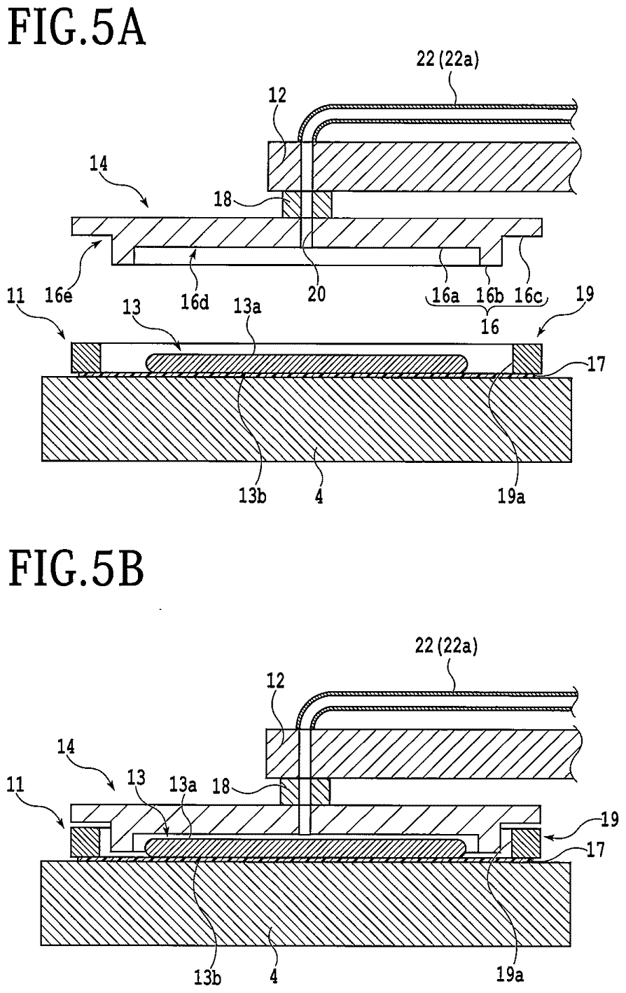

Specifically, in this method, the frame unit 11 and the pad 14 are first adjusted in position relative to each other (position adjusting step S1). FIG. 5A and FIG. 5B are each a cross-sectional view schematically illustrating how the position adjusting step S1 is performed.

In the position adjusting step S1, the X-direction moving mechanism 8 and/or the Z-direction moving mechanism 10 is operated to position the center of the communication passage 20 directly above the center of the transfer source table 4 without bringing the pad 14 into contact with the frame 19 (refer to FIG. 5A). The Z-direction moving mechanism 10 is then operated to make the first area 16a of the holding surface 16 of the pad 14 and the front surface 13a of the wafer 13 approach each other until a distance between them reaches a predetermined distance (0.3 mm, for example) (refer to FIG. 5B).

As a result, the wafer 13 faces the first area 16a of the holding surface 16 of the pad 14 and is surrounded by the second area 16b, and the frame 19 faces the third area 16c. Further, a portion of the sheet 17 positioned between the wafer 13 and the frame 19 faces the second area 16b. In other words, the second area 16b is surrounded by the wafer 13 and the frame 19.

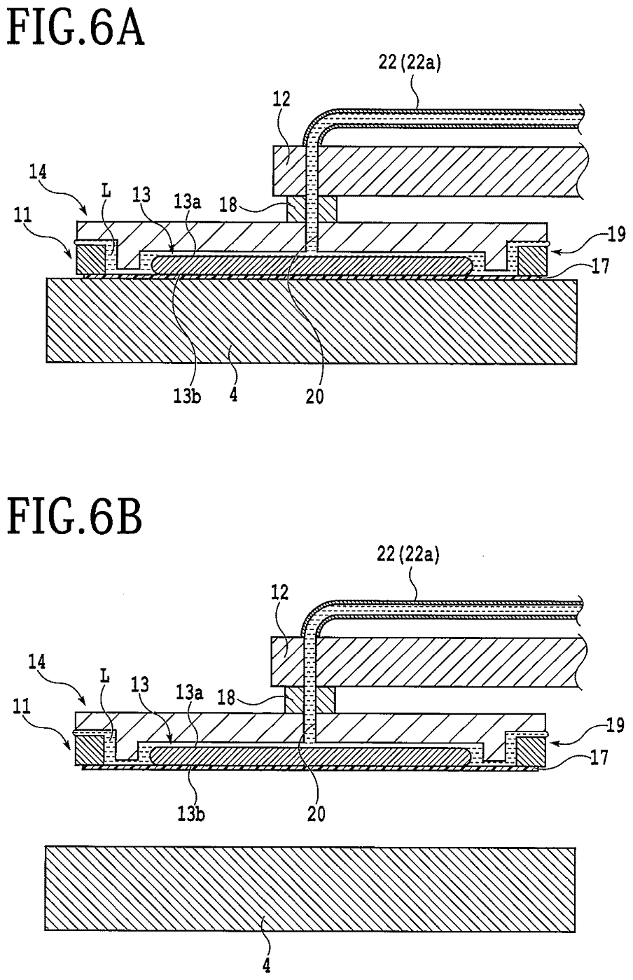

After the position adjusting step S1, the frame unit 11 is held on the holding surface 16 side of the pad 14 by use of interfacial tension of liquid in a still state (holding step S2). FIG. 6A is a cross-sectional view schematically illustrating how the holding step S2 is performed.

In the holding step S2, for example, the liquid supply unit 22 is operated to supply liquid L to the holding surface 16 side of the pad 14 until a gap between the third area 16c of the holding surface 16 of the pad 14 and the frame 19 is filled with the liquid L, and then the operation is stopped (refer to FIG. 6A).

Thus, gaps between the first area 16a of the holding surface 16 of the pad 14 and the wafer 13, and between the second area 16b of the holding surface 16 of the pad 14 and the wafer 13, a gap between the second area 16b and the sheet 17, and gaps between the second area 16b and the frame 19, and between the third area 16c and the frame 19 are filled with the liquid L in the still state. As a result, the frame unit 11 is held on the holding surface 16 side of the pad 14 by the action of the interfacial tension of the liquid L.

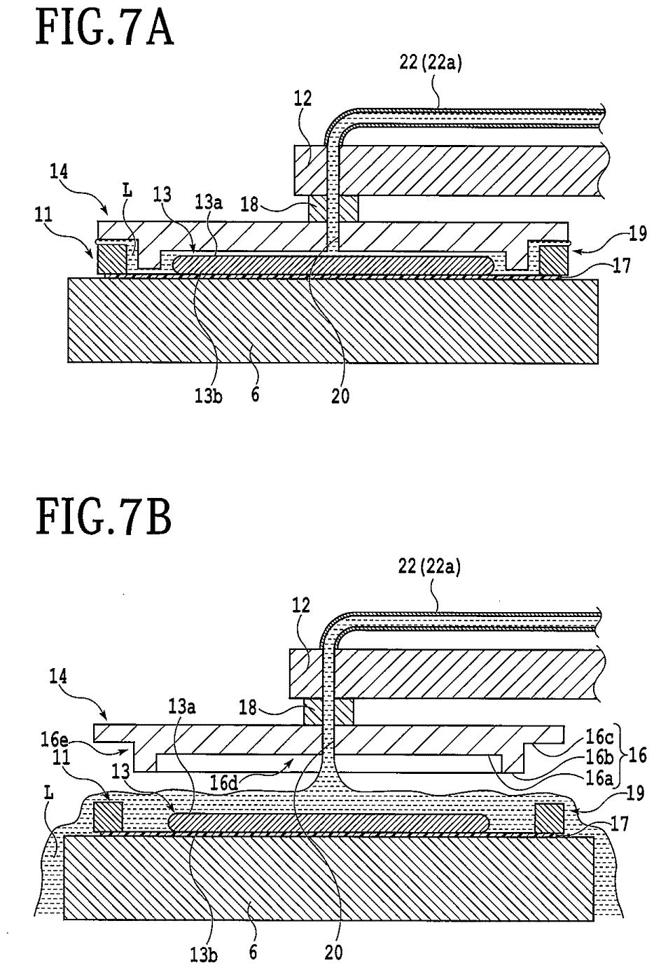

After the holding step S2, the frame unit 11 is transferred (transfer step S3). FIG. 6B, FIG. 7A, and FIG. 7B are each a cross-sectional view schematically illustrating how the transfer step S3 is performed. In the transfer step S3, first, the Z-direction moving mechanism 10 is operated to raise the frame unit 11 held on the holding surface 16 side of the pad 14 (refer to FIG. 6B).

Then, the X-direction moving mechanism 8 is operated to position the center of the communication passage 20 directly above the center of the transfer destination table 6, and the Z-direction moving mechanism 10 is then operated to bring the sheet 17 into contact with the transfer destination table 6 (refer to FIG. 7A). The Z-direction moving mechanism 10 is then operated to raise the pad 14 while the liquid supply unit 22 is operated to supply the liquid L to the holding surface 16 side of the pad 14 and to cause the liquid L to continuously overflow from the gap between the third area 16c and the frame 19 (refer to FIG. 7B).

At this time, the gaps between the first area 16a of the holding surface 16 of the pad 14 and the wafer 13, and between the second area 16b of the holding surface 16 of the pad 14 and the wafer 13, the gap between the second area 16b and the sheet 17, and the gaps between the second area 16b and the frame 19, and between the third area 16c and the frame 19 are filled with the liquid L in a flowing state. Therefore, the frame unit 11 is separated from the holding surface 16 side of the pad 14, so that the frame unit 11 is not raised. In this manner, transfer of the frame unit 11 to the transfer destination table 6 is completed.

When the frame unit transfer method indicated in FIG. 4 is performed using the transfer apparatus 2, the gaps between the first area 16a of the holding surface 16 of the pad 14 and the wafer 13, and between the second area 16b of the holding surface 16 of the pad 14 and the wafer 13 are filled with the liquid L in the still state. In this case, drying of the wafer 13 is prevented. Therefore, when the frame unit transfer method is performed in this manner, contamination can be prevented from adhering to the wafer 13.

Further, when the frame unit transfer method is performed in this manner, the frame unit 11 is held on the holding surface 16 side by use of the interfacial tension of the liquid L in the still state. In this case, it is not necessary to form grooves for causing a space in the vicinity of the holding surface 16 to become negatively pressurized according to the Bernoulli's theorem, in the holding surface 16 of the pad 14. Hence, when the frame unit transfer method is performed in this manner, manufacturing cost of the pad 14 can be reduced compared to a case in which such grooves are formed in the holding surface 16 of the pad 14.

Moreover, when the frame unit transfer method is performed in this manner, transfer of the frame unit 11 is performed by moving the pad 14 while the frame unit 11 is kept being held on the holding surface 16 side by use of the interfacial tension of the liquid L in the still state. In this case, no suction mechanism is required to transfer the frame unit 11. Therefore, when the frame unit transfer method is performed in this manner, operating cost can be reduced compared to a case in which such a suction mechanism is used to transfer the frame unit 11.

It is to be noted that the above description is one aspect of the present invention and that contents of the present invention are not limited to those described above. For example, in the present invention, a frame unit including a plate-shaped object other than the wafer 13 may be transferred. For example, in the present invention, a frame unit including a plurality of chips manufactured by division of the wafer 13 may be transferred.

Further, in the present invention, when the frame unit 11 is held and then transferred, the gap between the pad 14 and the frame unit 11 does not necessarily need to be entirely filled with the liquid L in the still state. For example, in the present invention, the frame unit 11 may be held and then transferred in a state in which the gap between the third area 16c of the holding surface 16 of the pad 14 and the frame 19 is not supplied with the liquid L, i.e., in a state in which this gap is left unfilled.

In addition, in the present invention, there may be used a transfer apparatus having, in place of the pad 14, a pad that is coupled to an elevating mechanism capable of adjusting a height of the first area 16a of the holding surface 16, at the distal end portion of the arm 12 through the coupling member 18. In this case, the first area 16a can be positioned at a suitable height according to the thickness of the wafer 13 or the like, so that convenience of the transfer apparatus is enhanced.

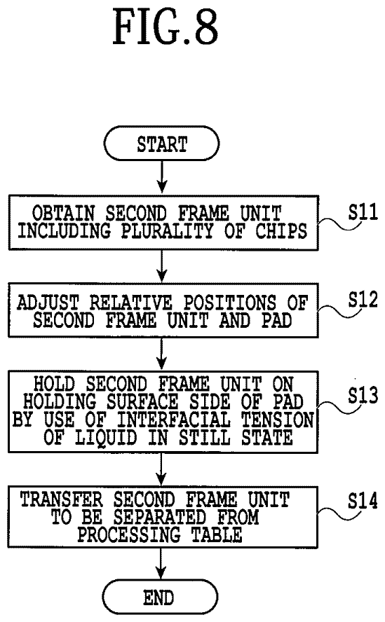

Moreover, the present invention may be a chip manufacturing method for manufacturing a plurality of chips from the wafer 13 of the frame unit (hereinafter referred to also as the first frame unit) 11. FIG. 8 is a flowchart schematically illustrating an example of this method.

Briefly, in this method, the frame unit transfer method described above is applied as a method for taking out a frame unit (second frame unit) including a plurality of chips manufactured by division of the wafer 13 from a table (processing table) for holding the wafer 13 at the time of processing the wafer 13.

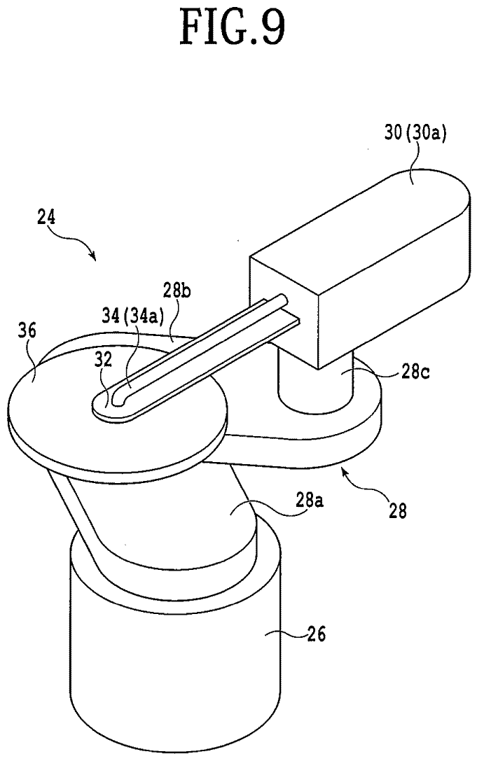

FIG. 9 is a perspective view schematically illustrating an example of a transfer apparatus used in the chip manufacturing method illustrated in FIG. 8, i.e., a transfer apparatus capable of taking out the second frame unit from the processing table.

A transfer apparatus 24 illustrated in FIG. 9 has a first driving portion 26 with a columnar shape extending along the vertical direction. The first driving portion 26 is, for example, an actuator (not illustrated) such as an air cylinder capable of moving a rod up and down. Further, the first driving portion 26 has, on an upper surface side thereof, an opening through which the rod passes.

A transfer arm 28 is coupled to an upper end of the rod. Hence, the transfer arm 28 is capable of moving along the vertical direction. That is, when the first driving portion 26 is actuated, the transfer arm 28 moves (up and down) along the vertical direction.

The transfer arm 28 has a plurality of joints. Specifically, the transfer arm 28 has a first arm portion 28a with a plate shape extending along a direction orthogonal to the vertical direction. The first arm portion 28a is coupled, on a lower side of one end portion thereof, to the upper end of the rod in a manner rotatable about a straight line along the vertical direction.

The first arm portion 28a is coupled, on an upper side of the other end thereof, to a lower side of a first joint portion (not illustrated) with a columnar shape. The first joint portion is coupled, on an upper side thereof, to a second arm portion 28b with a plate shape extending along a direction orthogonal to the vertical direction.

The second arm portion 28b is coupled, on a lower side of one end thereof, to the upper side of the other end of the first arm portion 28a through the first joint portion in a manner rotatable about a straight line along the vertical direction. The second arm portion 28b is coupled, on an upper side of the other end thereof, to a lower side of a second joint portion 28c with a columnar shape.

The second joint portion 28c is coupled, on an upper side thereof, to a second driving portion 30. The second driving portion 30 includes a case 30a with a rectangular parallelepiped shape extending along a direction perpendicular to the vertical direction. The case 30a has a side plate positioned on one end thereof, the side plate having two openings defined therein, and an arm 32 and a pipe 34a of a liquid supply unit 34 are inserted through the respective openings.

The case 30a accommodates an actuator for advancing and retracting the arm 32 and the pipe 34a along the direction in which the case 30a extends. Further, on a lower side of a distal end portion of the arm 32, a pad 36 for holding the first frame unit 11 or the second frame unit on a lower surface (holding surface) side thereof is provided.

The arm 32 and the pad 36 have structures similar to those of the arm 12 and the pad 14 illustrated in FIG. 2, FIGS. 3A and 3B, and the like, and a coupling member similar to the coupling member 18 illustrated in FIG. 2, FIGS. 3A and 3B, and the like is provided between the arm 32 and the pad 36. A communication passage similar to the communication passage 20 illustrated in FIG. 2, FIGS. 3A and 3B, and the like is formed through the center of each of the distal end portion of the arm 32, the pad 36, and the coupling member.

The communication passage communicates with the liquid supply unit 34. Specifically, the communication passage can communicate with a liquid supply source (not illustrated) through the pipe 34a. When the liquid supply source is actuated, liquid (water, for example) is supplied to the holding surface side of the pad 36 through the pipe 34a and the communication passage.

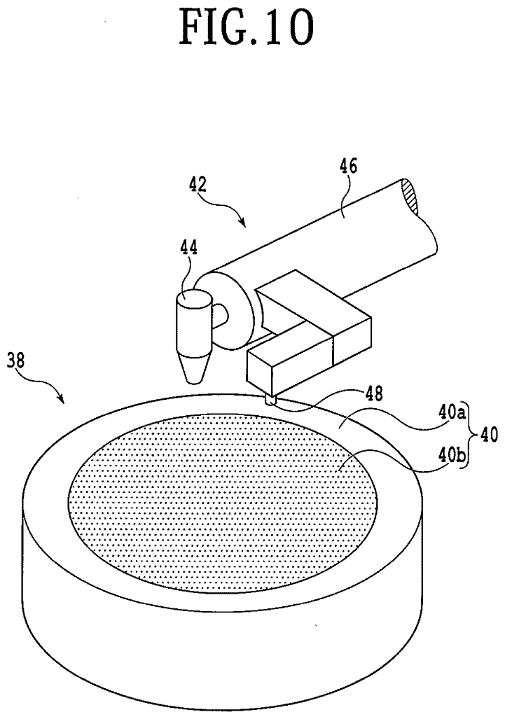

FIG. 10 is a perspective view schematically illustrating an example of a processing apparatus used in the chip manufacturing method illustrated in FIG. 8, that is, a processing apparatus capable of processing the wafer 13 such that the wafer 13 is divided along the boundaries of the plurality of devices 15 while the first frame unit 11 is held on the processing table.

A processing apparatus 38 illustrated in FIG. 10 includes a processing table 40 that has a circular upper surface (holding surface) of a diameter larger than a width of the first frame unit 11 and that can hold the first frame unit 11 on the holding surface. The processing table 40 has a disk-shaped frame body 40a.

The frame body 40a includes a disk-shaped bottom wall and a cylindrical side wall standing from an outer peripheral end portion of the bottom wall. Further, in a recessed portion defined by the bottom wall and the side wall of the frame body 40a, a disk-shaped porous plate 40b made of porous ceramics, for example, is fixed.

The porous plate 40b has a diameter substantially equal to an inner diameter of the side wall of the frame body 40a. The porous plate 40b is provided such that an upper surface of the porous plate 40b is flush with an upper surface of the side wall of the frame body 40a. Further, the porous plate 40b communicates with a suction source (not illustrated) including an ejector and the like through a flow path formed in the bottom wall of the frame body 40a.

To process the wafer 13 of the first frame unit 11 in the processing apparatus 38, the first frame unit 11 is placed on the holding surface of the processing table 40 such that the wafer 13 side is oriented upward and the porous plate 40b is covered. When the suction source communicating with the porous plate 40b is actuated in this state, suction force acts on the first frame unit 11. As a result, the first frame unit 11 having the wafer 13 exposed is held on the holding surface of the processing table 40.

Moreover, the processing table 40 is coupled to a rotation mechanism (not illustrated) including a motor and the like. When the rotation mechanism is actuated, the processing table 40 is rotated about a straight line passing through a center of the holding surface and extending along the vertical direction.

Above the processing table 40, a head 44 of a laser beam irradiation unit 42 is provided. The head 44 is provided at a distal end portion of a housing 46 with a cylindrical shape extending along a direction orthogonal to the vertical direction. It is to be noted that the head 44 accommodates an optical system including a condenser lens, a mirror, and the like and that the housing 46 accommodates an optical system including a mirror, a lens, and/or the like.

The housing 46 is coupled to a moving mechanism at a base end portion thereof. The moving mechanism has a ball screw, a motor, and the like, for example. When the moving mechanism is actuated, the housing 46 moves along a horizontal direction and/or the vertical direction. Further, the laser beam irradiation unit 42 has a laser oscillator (not illustrated) including an Nd: YAG laser medium or the like, for example.

The laser oscillator generates a laser beam having a wavelength (355 nm, for example) that is absorbed by the material of the wafer 13. The generated laser beam is adjusted by an attenuator to have its output (power) become a predetermined value, and then emitted directly downward from the head 44 through the optical systems accommodated in the housing 46 and the head 44.

Moreover, an imaging unit 48 capable of imaging a region directly below is provided at a side portion of the housing 46. The imaging unit 48 has, for example, a light source such as a light emitting diode (LED), an objective lens, and an imaging element such as a charge coupled device (CCD) image sensor or a complementary metal oxide semiconductor (CMOS) image sensor.

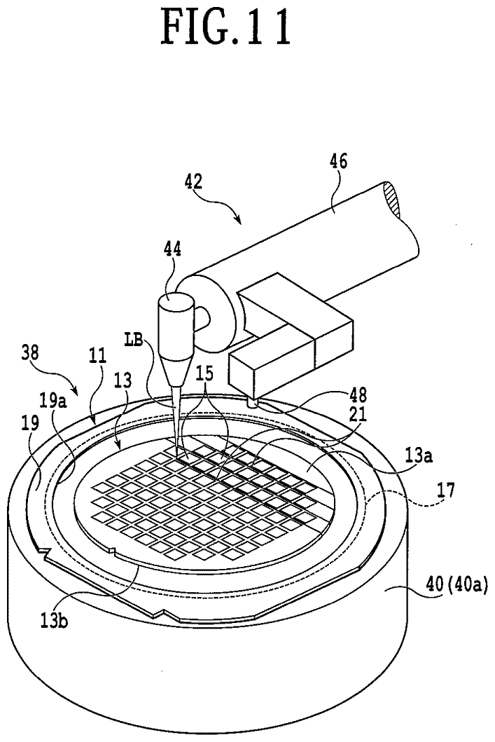

In the chip manufacturing method illustrated in FIG. 8, first, the second frame unit including a plurality of chips is obtained (chip manufacturing step S11). FIG. 11 is a perspective view schematically illustrating how the chip manufacturing step S11 is performed.

In the chip manufacturing step S11, first, the first frame unit 11 is placed on the holding surface of the processing table 40 such that the wafer 13 is oriented upward and the sheet 17 covers the porous plate 40b. Then, the suction source communicating with the porous plate 40b is operated to hold the first frame unit 11 on the holding surface of the processing table 40.

Next, the imaging unit 48 is operated to form an image of the wafer 13. Then, with reference to this image, the moving mechanism moves the housing 46 such that the head 44 is positioned directly above one end of a specific one of the planned division lines that are the boundaries of the plurality of devices 15.

Thereafter, the moving mechanism moves the housing 46 such that a focal point of a laser beam LB emitted from the head 44 is positioned at a height corresponding to the wafer 13. The moving mechanism then moves the housing 46 until the head 44 reaches a position directly above the other end of the planned division line, while the wafer 13 is irradiated with the laser beam LB with the focal point positioned inside the wafer 13.

The wafer 13 is thus subjected to laser ablation, and a portion overlapping the planned division line in the wafer 13 is removed, so that a linear groove 21 having a bottom surface positioned on the sheet 17 is formed. The operation described above is repeated as appropriate until all the portions overlapping the boundaries of the plurality of devices 15 in the wafer 13 are removed and, as a result, grooves in a lattice shape overlapping the boundaries are formed. Consequently, a plurality of chips are manufactured from the wafer 13. That is, the second frame unit including the plurality of chips is obtained.

After the chip manufacturing step S11, the second frame unit and the pad 36 are adjusted in position relative to each other (after-processing position adjusting step S12). The after-processing position adjusting step S12 is performed in the same manner as the position adjusting step S1 described above, for example, except that the position of the pad 36 is adjusted not by operating the X-direction moving mechanism 8 and the Z-direction moving mechanism 10 but by operating the first driving portion 26, the transfer arm 28, and the second driving portion 30.

After the after-processing position adjusting step S12, the second frame unit is held on the holding surface side of the pad 36 by use of interfacial tension of liquid in a still state (after-processing holding step S13). The after-processing holding step S13 is performed in the same manner as the holding step S2 described above.

After the after-processing holding step S13, the second frame unit is transferred to be separated from the processing table 40 (after-processing transfer step S14). The after-processing transfer step S14 is performed in the same manner as the transfer step S3 described above, for example, except that the position of the pad 36 is adjusted not by operating the X-direction moving mechanism 8 and the Z-direction moving mechanism 10 but by operating the first driving portion 26, the transfer arm 28, and the second driving portion 30. In addition, in the after-processing transfer step S14, the second frame unit may be transferred not to the transfer destination table 6 but, for example, into a cassette.

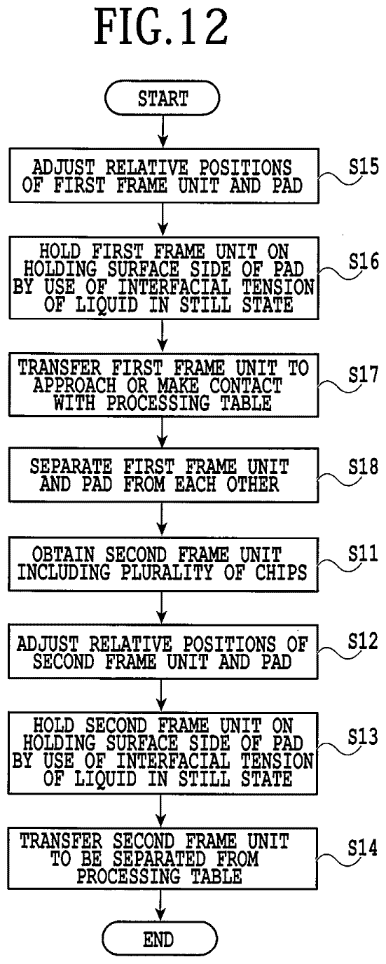

Moreover, the present invention may be a chip manufacturing method in which the frame unit transfer method described above is applied not only to the method for taking out the second frame unit from the processing table 40 but also to a method for carrying the first frame unit 11 onto the processing table 40. FIG. 12 is a flowchart schematically illustrating an example of this chip manufacturing method.

In the chip manufacturing method illustrated in FIG. 12, first, the first frame unit 11 and the pad 36 are adjusted in position relative to each other (before-processing position adjusting step S15). The before-processing position adjusting step S15 is performed in the same manner as the position adjusting step S1 described above, for example, except that the position of the pad 36 is adjusted not by operating the X-direction moving mechanism 8 and the Z-direction moving mechanism 10 but by operating the first driving portion 26, the transfer arm 28, and the second driving portion 30. Further, in the before-processing position adjusting step S15, instead of adjusting the position of the first frame unit 11 placed on the transfer source table 4 and the position of the pad 36 relative to each other, for example, the position of the first frame unit 11 accommodated in a cassette and the position of the pad 36 may be adjusted relative to each other.

After the before-processing position adjusting step S15, the first frame unit 11 is held on the holding surface side of the pad 36 by use of interfacial tension of liquid in a still state (before-processing holding step S16). The before-processing holding step S16 is performed in the same manner as the holding step S2 described above.

After the before-processing holding step S16, the first frame unit 11 is transferred to approach or make contact with the processing table 40 (before-processing transfer step S17), and the first frame unit 11 and the pad 36 are then separated from each other (separating step S18). The before-processing transfer step S17 and the separating step S18 are performed in the same manner as the transfer step S3 described above, for example, except that the position of the pad 36 is adjusted not by operating the X-direction moving mechanism 8 and the Z-direction moving mechanism 10 but by operating the first driving portion 26, the transfer arm 28, and the second driving portion 30.

After the separating step S18, the chip manufacturing step S11, the after-processing position adjusting step S12, the after-processing holding step S13, and the after-processing transfer step S14 described above are sequentially performed.

However, in the chip manufacturing method illustrated in FIG. 12, there is the possibility that the liquid is left on the first frame unit 11 held on the processing table 40. Therefore, in the chip manufacturing step S11, it is preferable that, after the first frame unit 11 is held on the holding surface of the processing table 40 but before the wafer 13 is imaged, for example, the rotation mechanism cause the processing table 40 to rotate in such a manner that centrifugal force is made to act on the liquid left on the wafer 13, thereby making the liquid flow off outwardly.

It is to be noted that the processing apparatus used in the chip manufacturing method illustrated in FIG. 8 or FIG. 12 is not limited to the laser processing apparatus that processes the wafer 13 by use of the laser beam LB, and may be a cutting apparatus capable of processing the wafer 13 by use of an annular cutting blade, for example. That is, in the chip manufacturing step S11, a plurality of chips may be manufactured from the wafer 13 by causing the cutting blade to cut into the wafer 13 along the boundaries of the plurality of devices 15.

Besides, the structures, methods, and the like related to the embodiments described above can be implemented in various modified manners as needed without departing from the scope of the object of the present invention.

The present invention is not limited to the details of the above described preferred embodiments. The scope of the invention is defined by the appended claims and all changes and modifications as fall within the equivalence of the scope of the claims are therefore to be embraced by the invention.

What is claimed is:

1. A transfer apparatus for transferring a frame unit including a plate-shaped object, a frame surrounding the plate-shaped object, and a sheet fixed to both the plate-shaped object and the frame, the transfer apparatus comprising:
a pad for holding the frame unit on a holding surface side thereof;
a liquid supply unit configured to supply liquid to the holding surface side of the pad; and
a moving mechanism configured to move the pad,
wherein the holding surface has a first area and a second area surrounding the first area and protruding with respect to the first area, and,
in a state in which the first area faces the plate-shaped object and the second area surrounds the plate-shaped object, the frame unit is held on the holding surface side by use of interfacial tension of the liquid in a still state, the liquid being supplied from the liquid supply unit and filling gaps between the first area and the plate-shaped object, and between the second area and the plate-shaped object, and then the moving mechanism moves the pad to transfer the frame unit.

2. The transfer apparatus according to claim 1,
wherein the frame unit is transferred in a state in which the second area faces a portion of the sheet positioned between the plate-shaped object and the frame.

3. The transfer apparatus according to claim 1,
wherein the holding surface further has a third area surrounding the second area and being recessed with respect to the second area, and
the frame unit is transferred in a state in which the third area faces the frame.

4. The transfer apparatus according to claim 1,
wherein the liquid supply unit supplies the liquid through a communication passage that is open in the first area.

5. A frame unit transfer method for transferring a frame unit including a plate-shaped object, a frame surrounding the plate-shaped object, and a sheet fixed to both the plate-shaped object and the frame, the frame unit transfer method comprising:
adjusting the frame unit and a pad in position relative to each other such that a first area of a holding surface of the pad faces the plate-shaped object and that a second area surrounding the first area and protruding with respect to the first area surrounds the plate-shaped object;
after the frame unit and the pad are adjusted in position relative to each other, holding the frame unit on the holding surface side by use of interfacial tension of liquid in a still state, the liquid filling gaps between the first area and the plate-shaped object, and between the second area and the plate-shaped object; and
transferring the frame unit by moving the pad while the frame unit is kept being held on the holding surface side by use of the interfacial tension of the liquid in the still state, the liquid filling the gaps.

6. A chip manufacturing method for manufacturing a plurality of chips from a wafer of a first frame unit including the wafer having a plurality of devices formed thereon, a frame surrounding the wafer, and a sheet fixed to both the wafer and the frame, the chip manufacturing method comprising:
obtaining a second frame unit including a plurality of chips manufactured by division of the wafer along boundaries of the plurality of devices on a processing table;
adjusting the second frame unit and a pad in position relative to each other such that a first area of a holding surface of the pad faces the plurality of chips and that a second area surrounding the first area and protruding with respect to the first area surrounds the plurality of chips;
after the second frame unit and the pad are adjusted in position relative to each other, holding the second frame unit on the holding surface side by use of interfacial tension of liquid in a still state, the liquid filling gaps between the first area and the plurality of chips, and between the second area and the plurality of chips; and
transferring the second frame unit to be separated from the processing table by moving the pad while the second frame unit is kept being held on the holding surface side by use of the interfacial tension of the liquid in the still state, the liquid filling the gaps.
